(19) United States
(12) Patent Application Publication
(10) Pub. No.: US 2025/0240900 A1
(43) Pub. Date: Jul. 24, 2025

(54) ELECTRONIC DEVICE COMPRISING PRINTED CIRCUIT BOARD FASTENED INSIDE HOUSING

(71) Applicant: Samsung Electronics Co., Ltd., Suwon-si (KR)

(72) Inventor: Jinhwan JEON, Suwon-si (KR)

(21) Appl. No.: 19/174,385

(22) Filed: Apr. 9, 2025

Related U.S. Application Data
(63) Continuation of application No. PCT/KR2023/014002, filed on Sep. 15, 2023.

(30) Foreign Application Priority Data
Oct. 17, 2022 (KR) 10-2022-0133597
Nov. 18, 2022 (KR) 10-2022-0155862

(51) Int. Cl. H05K 5/00; H05K 1/11

(52) U.S. Cl. CPC H05K 5/0069; H05K 1/116

(57) ABSTRACT

An electronic device is provided. The electronic device includes a housing, a printed circuit board including an insertion hole, disposed within the housing, at least one electronic component disposed on a surface of the printed circuit board, and a fastening member inserted into the insertion hole to fasten the printed circuit board to the housing, wherein the printed circuit board further includes a ground pad disposed on one surface of the printed circuit board along the insertion hole, a test pad disposed on one surface of the printed circuit board along the ground pad, a first conductive pad disposed between the test pad and the electronic component, electrically connected to the test pad, and a second conductive pad, disposed between the first conductive pad and the electronic component, spaced apart from the first conductive pad to be electrically disconnected from the first conductive pad, and electrically connected to the electronic component, and wherein the fastening member is electrically connected to the ground pad and the test pad by a portion of the fastening member being in contact with the ground pad and the test pad.

### CROSS-REFERENCE TO RELATED APPLICATION(S)

This application is a continuation application, claiming priority under 35 U.S.C. § 365(c), of an International application No. PCT/KR2023/014002, filed on Sep. 15, 2023, which is based on and claims the benefit of a Korean patent application number 10-2022-0133597, filed on Oct. 17, 2022, in the Korean Intellectual Property Office, and of a Korean patent application number 10-2022-0155862, filed on Nov. 18, 2022, in the Korean Intellectual Property Office, the disclosure of each of which is incorporated by reference herein in its entirety.

### BACKGROUND

### 1. Field

The disclosure relates to an electronic device comprising a printed circuit board fastened inside a housing.

### 2. Description of Related Art

An electronic device may be miniaturized to meet a need of a user. As the electronic device is miniaturized, a size of a space in which electronic components may be disposed within the electronic device may be reduced. The electronic device may include a printed circuit board on which the electronic components may be disposed within the miniaturized electronic device. The printed circuit board may be fastened into the electronic device through a fastening member to maintain a position within the electronic device.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device comprising a printed circuit board fastened inside a housing.

Additional aspects will be set forth in part in the description which follows and, in part, will be apparent from the description, or may be learned by practice of the presented embodiments.

In accordance with an aspect of the disclosure, an electronic device is provided. The electronic device includes a housing, a printed circuit board, including an insertion hole, disposed within the housing, at least one electronic component disposed on a surface of the printed circuit board, and a fastening member inserted into the insertion hole to fasten the printed circuit board to the housing, wherein the printed circuit board further includes a ground pad disposed on the surface of the printed circuit board along the insertion hole, a test pad disposed on the surface of the printed circuit board along the ground pad, a first conductive pad, disposed between the test pad and the electronic component, electrically connected to the test pad, and a second conductive pad, disposed between the first conductive pad and the electronic component, spaced apart from the first conductive pad to be electrically disconnected from the first conductive pad, and electrically connected to the electronic component, and wherein the fastening member is electrically connected to the ground pad and the test pad by a portion of the fastening member being in contact with the ground pad and the test pad.

In accordance with another aspect of the disclosure, an electronic device is provided. The electronic device includes a housing, a printed circuit board, including an insertion hole, disposed within the housing, at least one electronic component disposed on a surface of the printed circuit board, and a fastening member fastening the printed circuit board into the housing by being inserted into the insertion hole, wherein the printed circuit board further includes a ground pad disposed along the insertion hole, a plurality of test pads, surrounding the ground pad, exposed on the surface of the printed circuit board, and spaced apart from each other, sets of a plurality of conductive pads that include a first conductive pad and a second conductive pad spaced apart from the first conductive pad to be electrically disconnected from the first conductive pad, and that are disposed between the insertion hole and the electronic component, a first conductive line connecting the first conductive pad and one of the plurality of test pads, a second conductive line connecting the second conductive pad and the electronic component, and a ground layer, electrically disconnected from the second conductive line, electrically connected to the ground pad, and wherein the fastening member is electrically connected to the ground layer by a portion of the fastening member being in contact with at least some of the ground pad and the plurality of test pads.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates an example of a block diagram of an electronic device within a network environment according to an embodiment of the disclosure;

FIG. 2A illustrates an example of a prospective view of an electronic device according to an embodiment of the disclosure;

FIG. 2B illustrates an example of one or more hardware disposed within an electronic device according to an embodiment of the disclosure;

FIG. 3A is a top plan view of a printed circuit board disposed within an electronic device according to an embodiment of the disclosure;

FIG. 3B is a cross-sectional view illustrating an example of a printed circuit board cut along line A-A′ of FIG. 3A, according to an embodiment of the disclosure; and

FIG. 4 is a top plan view of a printed circuit board according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

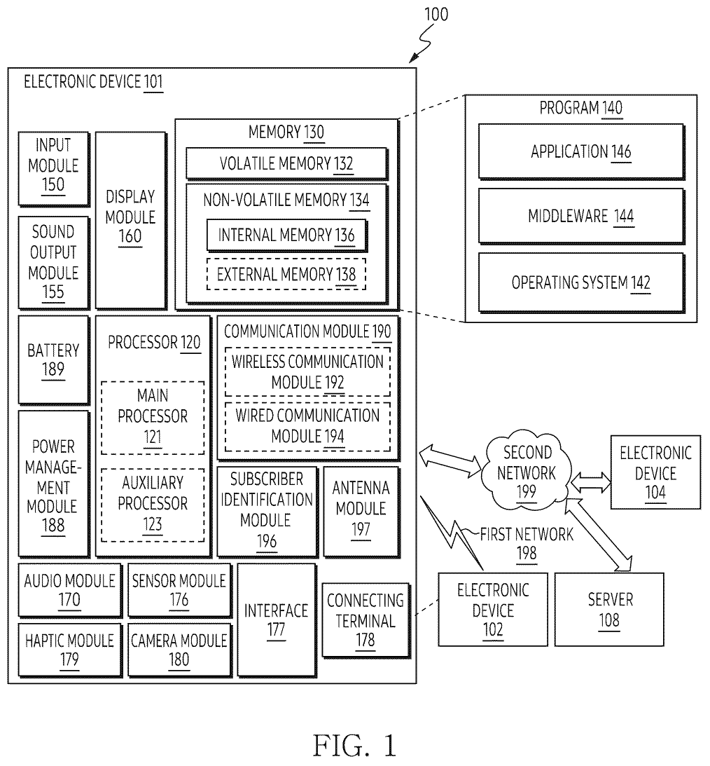

FIG. 1 is a block diagram illustrating an electronic device in a network environment according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter-wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102 or 104 or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

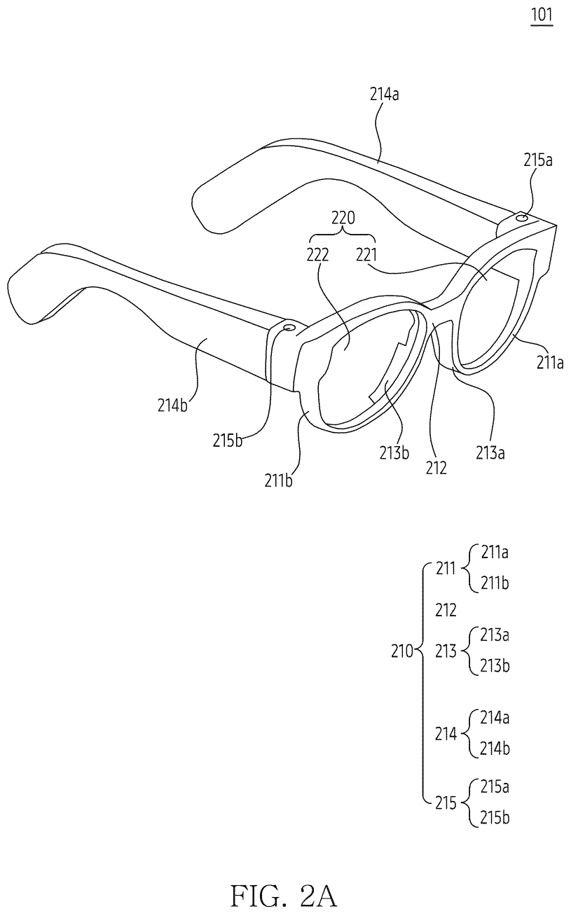

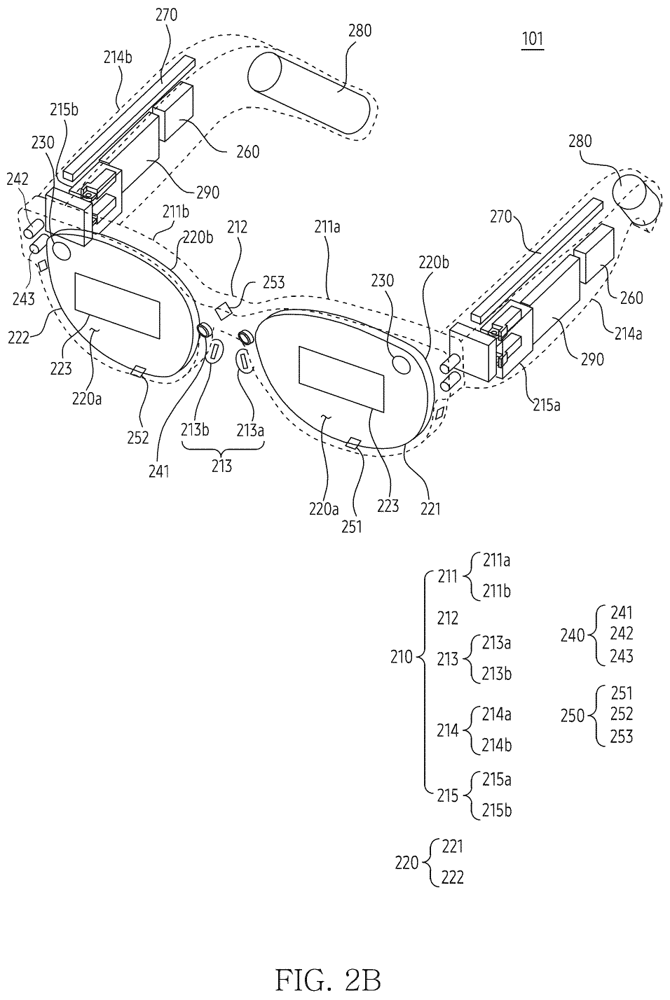

FIG. 2A illustrates an example of a prospective view within a wearable device according to an embodiment of the disclosure. FIG. 2B illustrates an example of one or more hardware disposed within a wearable device according to an embodiment of the disclosure.

Referring to FIGS. 2A and 2B, according to an embodiment, an electronic device 101 (e.g., the electronic device 101 of FIG. 1) may include a portion or all of components of the electronic device 101 of FIG. 1. According to an embodiment, the electronic device 101 may include a housing 210, at least one display 220, at least one optical device 230, at least one camera 240 (e.g., the camera module 180 of FIG. 1), at least one microphone 250, a speaker 260, an antenna module 270 (e.g., the antenna module 197 of FIG. 1), a battery 280 (e.g., the battery 189 of FIG. 1), and/or a printed circuit board 290. According to an embodiment, the electronic device 101 may be referred to as a wearable device worn on a portion of a body of a user. The electronic device 101 may be configured to provide augmented reality (AR), virtual reality (VR), or mixed reality (MR) that combines the augmented reality and the virtual reality to the user. For example, the electronic device 101 may be configured to provide the augmented reality through the display 220 that displays a real image provided by light received from an outside of the electronic device 101 and a virtual object overlapping the real image. The real image may be implemented by the light received from the outside of the electronic device 101 without separate data processing by the electronic device 101. The virtual object may include at least one of text and an image corresponding to various information related to an object in the real image. However, it is not limited thereto, and the virtual object may include at least one of text and an image corresponding to various information related to another object not included in the real image.

The housing 210 may form at least a portion of an outer surface of the electronic device 101. At least a portion of the housing 210 may be in contact with a portion of the body of the user when the electronic device 101 is worn on the user. According to an embodiment, the housing 210 may support the components included in the electronic device 101. For example, a portion of the components included in the electronic device 101 may be disposed inside the housing 210. For example, another portion of the components included in electronic device 101 may be exposed to an outside of the housing 210. According to an embodiment, the housing 210 may include at least one rim 211, a bridge 212, at least one nose pad 213, at least one temple 214, and/or a hinge structure 215.

The at least one rim 211 may support the display 220. When the electronic device 101 is worn by the user, the at least one rim 211 may be worn at a position corresponding to eyes of the user. According to an embodiment, the at least one rim 211 may include a first rim 211a and a second rim 211b. The first rim 211a and the second rim 211b may be spaced apart from each other. For example, when the electronic device 101 is worn by the user, the first rim 211a may be positioned to correspond to a left eye of the user, and the second rim 211b may be positioned to correspond to a right eye of the user.

The bridge 212 may be coupled to the at least one rim 211. According to an embodiment, the bridge 212 may connect the first rim 211a and the second rim 212b. For example, the bridge 212 may extend between a periphery of the first rim 211a and a periphery of the second rim 211b. When the electronic device 101 is worn by the user, the bridge 212 may be positioned between the left eye and the right eye of the user.

The at least one nose pad 213 may maintain a position of the electronic device 101 when the electronic device 101 is worn by the user. For example, when the electronic device 101 is worn by the user, the at least one nose pad 213 may be in contact with a nose of the user. According to an embodiment, the at least one nose pad 213 may include a first nose pad 213a and a second nose pad 213b spaced apart from the first nose pad 213a. For example, when the electronic device 101 is worn by the user, the first nose pad 213a may be disposed on the periphery of the first rim 211a facing the user. For example, when the electronic device 101 is worn by the user, the second nose pad 213b may be disposed on the periphery of the second rim 211b facing the user.

The at least one temple 214 may maintain the position of the electronic device 101 when the electronic device 101 is worn by the user. For example, when the electronic device 101 is worn by the user, the at least one temple 214 may be in contact with ears of the user. According to an embodiment, the at least one temple 214 may be coupled to the at least one rim 211. For example, the at least one temple 214 may include a first temple 214a coupled to the first rim 211a and a second temple 214b coupled to the second rim 211b. According to an embodiment, the at least one temple 214 may provide the space in which the components of the electronic device 101 are disposed.

The hinge structure 215 may connect the at least one rim 211 and the at least one temple 214. The hinge structure 215 may couple the at least one temple 214 and the at least one rim 211 so that the at least one temple 214 is rotatable with respect to the at least one rim 211. For example, the first temple 214a may be rotatably coupled with respect to the first rim 211a through the hinge structure 215a. For example, the second temple 214b may be rotatably coupled with respect to the second rim 211b through the hinge structure 215b.

The at least one display 220 may be configured to display visual information to the user. The at least one display 220 may include a substantially transparent or translucent lens. For example, the at least one display 220 may be referred to as a see-through display, but is not limited thereto. According to an embodiment, the at least one display 220 may be surrounded by the at least one rim 211. For example, the at least one display 220 may include a first display 221 and a second display 222. The second display 222 may be spaced apart from the first display 221. The first display 221 may be coupled to the first rim 211a, and the second display 222 may be coupled to the second rim 211b.

Referring to FIG. 2B, according to an embodiment, the at least one display 220 may include a first surface 220a and a second surface 220b opposite the first surface 220a. The at least one display 220 may include a display region disposed on the second surface 220b. For example, light incident through the first surface 220a from the outside of the electronic device 101 may pass through the first surface 220a and the second surface 220b. The light passing through the second surface 220b may be transmitted to the user.

According to an embodiment, the at least one display 220 may include a wave guide 223. The wave guide 223 may transmit the light transmitted from the at least one optical device 230 to the user based on changing a propagation direction of the light transmitted from the at least one optical device 230. The light emitted from the at least one optical device 230 may be transmitted to the user by passing through the second surface 220b of the at least one display 220 by the wave guide 223. For example, the wave guide 223 may transmit the light emitted from the at least one optical device 230 to the user by diffracting the light emitted from the at least one optical device 230 within the wave guide 223. In case that the wave guide 223 diffracts the light emitted from the at least one optical device 230, the wave guide 223 may include a diffractive element (e.g., a diffractive optical element (DOE) or a holographic optical element (HOE)) disposed within the wave guide 223. For example, by reflecting the light emitted from the at least one optical device 230 within the wave guide 223, the wave guide 223 may transmit it to the user. When the wave guide 223 reflects the light emitted from the at least one optical device 230, the wave guide 223 may include a plurality of mirrors disposed within the wave guide 223.

The at least one optical device 230 may emit light for displaying a virtual object on the at least one display 220. For example, the at least one optical device 230 may include a projector. For example, the electronic device 101 may transmit data for displaying the virtual object to the at least one optical device 230. The at least one optical device 230 may emit the light toward the wave guide 223, based on receiving the data for displaying the virtual object. The wave guide 223 may transmit the light received from the at least one optical device 230 to the display region on the second surface 220b of the display 220. The light emitted by the at least one optical device 230 may be transmitted to the user together with light implementing a real image transferred from the outside of the electronic device 101 by passing through the second surface 220b. The light emitted from the at least one optical device 230 and the light transferred from the outside of the electronic device 101 may provide the augmented reality to the user. According to an embodiment, the at least one optical device 230 may be disposed on the at least one display 220. For example, the at least one optical device 230 may be surrounded by the at least one rim 211, but is not limited thereto. For example, the at least one optical device 230 may be included within the at least one display 220.

The at least one camera 240 may be configured to obtain an image based on receiving light from an external object of the electronic device 101. According to an embodiment, the at least one camera 240 may include an eye tracking camera 241, a gesture recognition camera 242, and/or a shooting camera 243.

The eye tracking camera 241 may output data indicating a gaze of the user wearing the electronic device 101. For example, the electronic device 101 may detect the gaze from an image including a pupil of the user obtained through the eye tracking camera 241. According to an embodiment, the eye tracking camera 241 may include a plurality of eye tracking cameras corresponding to the left eye of the user and the right eye of the user, respectively. According to an embodiment, the electronic device 101 may match the gaze of the user with visual information provided to the at least one display 220 through the eye tracking camera 241 for tracking the gaze of the user wearing the electronic device 101. The eye tracking camera 241 may be configured to capture an image of a pupil of the user to determine the gaze of the user. For example, the eye tracking camera 241 may be configured to capture an image of the pupil of the user to determine the gaze of the user. For example, the eye tracking camera 241 may receive gaze detection light reflected from the pupil of the user and track the gaze of the user based on a position and a motion of the received gaze detection light. According to an embodiment, the eye tracking camera 241 may be disposed within the housing 210. The eye tracking camera 241 may be disposed in the housing 210 to direct the left eye and/or the right eye of the user. For example, the eye tracking camera 241 may be disposed on the at least one rim 211, but is not limited thereto. For example, the eye tracking camera 241 may be disposed on the bridge 212.

The gesture recognition camera 242 may provide a specific event to a screen provided to the at least one display 220 by recognizing a motion of at least a portion (e.g., a torso, a hand, or a face of the user) of the body of the user. The gesture recognition camera 242 may obtain a signal corresponding to the gesture for gesture recognition of the user, and provide a display corresponding to the signal to the at least one display 220. The electronic device 101 may identify the signal corresponding to the gesture and perform a designated function based on the identification. For example, the electronic device 101 may be turned on/off based on identifying the signal corresponding to the gesture. For example, the electronic device 101 may display a virtual object on the at least one display 220 through the at least one optical device 230 based on identifying the signal corresponding to the gesture. According to an embodiment, the gesture recognition camera 242 may be disposed within the housing 210. For example, the gesture recognition camera 242 may be disposed inside the at least one rim 211, but is not limited thereto. For example, the gesture recognition camera 242 may be disposed inside the bridge 212.

The shooting camera 243 may shoot a real image or a background to be matched with a virtual image to implement the augmented reality content or the mixed reality content. The shooting camera 243 may shoot an image of a specific object existing at a position where the user is looking and the electronic device 101 may provide the image obtained by the shooting camera 243 to the at least one display 220. The at least one display 220 may display a video in which information on the real image or background including the image of the specific object obtained by using the shooting camera 243 and the virtual image provided through the at least one optical device 230 are overlapped. According to an embodiment, the shooting camera 243 may be disposed inside the at least one rim 211. For example, the shooting camera 243 may include a plurality of shooting cameras spaced apart from each other.

The at least one microphone 250 may be configured to obtain an audio from the outside of the electronic device 101. According to an embodiment, the at least one microphone 250 may be disposed inside the housing 210. For example, the at least one microphone 250 may include a first microphone 251, a second microphone 252, and/or a third microphone 253. The first microphone 251 may be disposed inside the first rim 211a. The second microphone 252 may be disposed inside the second rim 211b. The third microphone 253 may be disposed between the first microphone 251 and the second microphone 252. For example, the third microphone 253 may be disposed within the bridge 212 of the housing 210. However, it is not limited thereto, and the number and disposition of the at least one microphone 250 may be changed differently from FIG. 2B. For example, the at least one microphone 250 may be disposed inside the at least one temple 214. According to an embodiment, when the number of at least one microphone 250 included within the electronic device 101 is two or more, the electronic device 101 may identify a direction of a sound signal using a plurality of microphones 251, 252, and 253 disposed on different portions of the housing 200.

The speaker 260 may be configured to output the audio to the outside of the electronic device 101. According to an embodiment, the speaker 260 may be positioned to be adjacent to the ears of the user while the electronic device 101 is worn on the user. For example, the speaker 260 may be disposed inside the at least one temple 214 in contact with the ears of the user. For example, the speaker 260 may be disposed inside the first temple 214a to be adjacent to the left ear of the user. For example, the speaker 260 may be disposed inside the second temple 214b to be adjacent to the right ear of the user.

The antenna module 270 may transmit a signal or power to the outside of the electronic device 101 or may receive a signal or power from the outside of the electronic device 101. The antenna module 270 may be electrically and/or operatively connected to communication circuitry. According to an embodiment, the antenna module 270 may be disposed within the at least one temple 214. For example, the antenna module 270 may be disposed inside the first temple 214a. For example, the antenna module 270 may be disposed inside the second temple 214b. According to an embodiment, at least a portion of the antenna module 270 may be exposed to an outside of the at least one temple 214, but is not limited thereto.

The battery 280 may supply power to the electronic components of the electronic device 101. According to an embodiment, the battery 280 may be disposed within the at least one temple 214. For example, the battery 280 may be disposed inside the first temple 214a. For example, the battery 280 may be disposed inside the second temple 214b. According to an embodiment, the battery 280 may be disposed in another end of the at least one temple 214 opposite to an end of the at least one temple 214 connected to the at least one rim 211. For example, the battery 280 may be disposed inside another end of the first temple 214a opposite to an end of the first temple 214a connected to the first rim 211a. For example, the battery 280 may be disposed inside another end of the second temple 214b opposite to an end of the second temple 214b connected to the second rim 211b.

The printed circuit board 290 may form an electrical connection between the electronic components within the electronic device 101. For example, the printed circuit board 290 may form the electrical connection between the electronic components disposed on the printed circuit board 290. For example, the printed circuit board 290 may form the electrical connection between the electronic components disposed outside the printed circuit board 290 and the electronic components (e.g., the processor 120 of FIG. 1) disposed on the printed circuit board 290. According to an embodiment, the printed circuit board 290 may be disposed inside the at least one temple 214. For example, the printed circuit board 290 may include a plurality of printed circuit boards disposed inside the first temple 214a and the second temple 214b, respectively. The printed circuit board 290 may include a flexible printed circuit board (FPCB) for connecting the plurality of printed circuit boards.

For example, as the electronic device 101 is miniaturized to be worn by the user, a size of a space in which the electronic components may be disposed within the housing 200 may be reduced. The printed circuit board 290 may be fastened into the housing 200 to maintain a designated position within the housing 200. For example, the printed circuit board 290 may be fastened into the housing 200 through a fastening member (e.g., a screw) extending through at least a portion of the printed circuit board 290. Due to a hole for accommodating the fastening member, the size of the space on the printed circuit board 290 in which the electronic components may be disposed may be reduced. Hereinafter, the printed circuit board 290 including a structure capable of utilizing the hole for accommodating the fastening member for various purposes will be described.

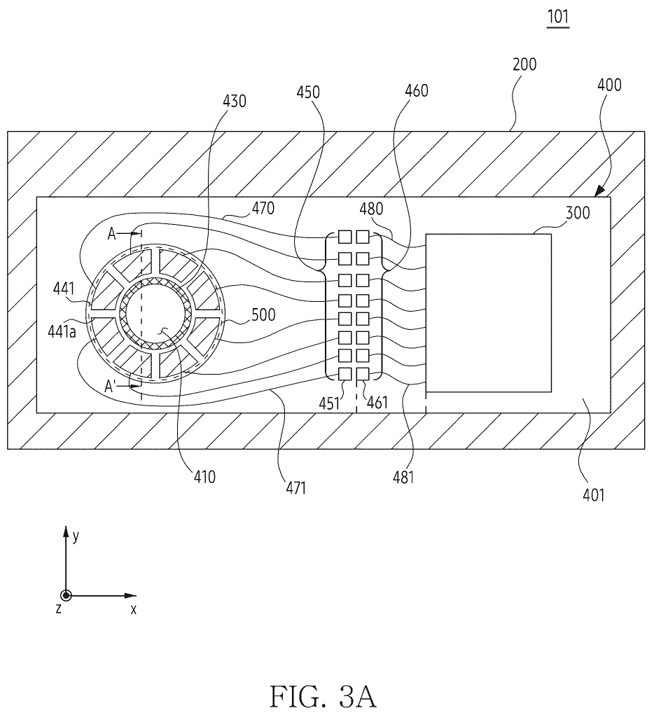

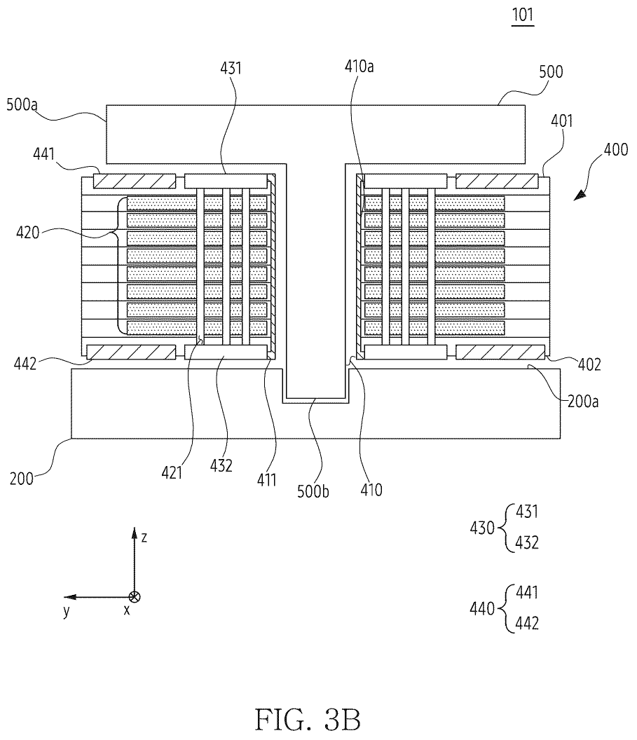

FIG. 3A is a top plan view of a printed circuit board disposed within an electronic device according to an embodiment of the disclosure, and FIG. 3B is a cross-sectional view illustrating an example of a printed circuit board cut along line A-A′ of

FIG. 3A, according to an embodiment of the disclosure.

Referring to FIGS. 3A and 3B, an electronic device 101 according to an embodiment may include a housing 200, at least one electronic component 300, a printed circuit board 400 (e.g., the printed circuit board 290 of FIG. 2B), and/or a fastening member 500.

The housing 200 may accommodate the printed circuit board 400. For example, the housing 200 may cover at least a portion of the printed circuit board 400. According to an embodiment, at least a portion of the housing 200 may include a conductive material. For example, the conductive material may include a metal material (e.g., copper, aluminum, or stainless used steel (SUS)). For example, the conductive material may include a composite material in which the metal material and a filler (e.g., polymeric materials such as carbon fiber, carbon black, carbon nanotube (CNT), or nickel-coated graphite) are mixed.

The at least one electronic component 300 may be configured to provide various functions of the electronic device 101. For example, the at least one electronic component 300 may be a processor (e.g., the processor 120 of FIG. 1), but is not limited thereto. According to an embodiment, the at least one electronic component 300 may be disposed on a surface 401 of the printed circuit board 400. For example, the at least one electronic component 300 may protrude from the surface 401 of the printed circuit board 400 in a direction (e.g., a +z direction) in which the surface 401 of the printed circuit board 400 faces. For example, the at least one electronic component 300 may be electrically connected to the printed circuit board 400 through solder.

The printed circuit board 400 may establish electrical connection between electronic components within the electronic device 101. According to an embodiment, the printed circuit board 400 may support the electronic component 300. For example, the surface 401 of the printed circuit board 400 may support the electronic component 300. According to an embodiment, the printed circuit board 400 may include an insertion hole 410.

The insertion hole 410 may accommodate the fastening member 500 for fastening the printed circuit board 400 and the housing 200. The insertion hole 410 may extend through at least a portion of the printed circuit board 400. For example, the insertion hole 410 may extend from the surface 401 of the printed circuit board 400 to another surface 402 of the printed circuit board 400 opposite to the surface 401 of the printed circuit board 400. A direction (e.g., a −z direction) in which the another surface 402 of the printed circuit board 400 faces may be opposite to the direction (e.g., the +z direction) in which the surface 401 of the printed circuit board 400 faces. However, it is not limited thereto, and the insertion hole 410 may extend through only a portion of the printed circuit board 400. According to an embodiment, a first conductive via 411 may be disposed inside the insertion hole 410. The first conductive via 411 may surround the insertion hole 410. For example, the first conductive via 411 may be disposed on an inner surface 410a of the insertion hole 410. For example, the first conductive via 411 may include a metal material (e.g., copper or platinum), but is not limited thereto. Although FIG. 3B illustrates that the first conductive via 411 is disposed within the insertion hole 410, it is not limited thereto. The first conductive via 411 may be omitted.

According to an embodiment, the fastening member 500 may fasten the printed circuit board 400 to the housing 200. According to an embodiment, the fastening member 500 may extend through the printed circuit board 400. For example, the fastening member 500 may be inserted into the insertion hole 410 of the printed circuit board 400. The fastening member 500 may pass through the insertion hole 410. According to an embodiment, a portion 500a of the fastening member 500 may be disposed on the surface 401 of the printed circuit board 400. The fastening member 500 may be in contact with the housing 200 by passing through the insertion hole 410. The fastening member 500 may be inserted into the housing 200 by passing through the insertion hole 410. For example, another portion 500b of the fastening member 500 may be accommodated in a recess formed on an inner surface 200a of the housing 200 facing the another surface 402 of the printed circuit board 400. According to an embodiment, the fastening member 500 may include a conductive material. For example, the conductive material may include at least one selected from a metal material, a filler, and a combination thereof.

According to an embodiment, the printed circuit board 400 may include at least one ground layer 420 and/or at least one ground pad 430. The at least one ground layer 420 may form an electrical ground of the printed circuit board 400. The at least one ground layer 420 may be disposed within the printed circuit board 400. According to an embodiment, the at least one the ground layer 420 may include a plurality of ground layers stacked on each other within the printed circuit board 400.

The at least one ground pad 430 may be electrically connected to the at least one ground layer 420. According to an embodiment, the at least one ground pad 430 may be disposed along the insertion hole 410. For example, the at least one ground pad 430 may cover the insertion hole 410. For example, the at least one ground pad 430 may surround the insertion hole 410. According to an embodiment, the at least one ground pad 430 may be exposed to an outside of the printed circuit board 400. The at least one ground pad 430 may include a first ground pad 431 and/or a second ground pad 432. The first ground pad 431 may be disposed on the surface 401 of the printed circuit board 400. For example, the first ground pad 431 may be exposed on the surface 401 of the printed circuit board 400. The second ground pad 432 may be disposed on the another surface 402 of the printed circuit board 400. For example, the second ground pad 432 may be exposed on the another surface 402 of the printed circuit board 400. According to an embodiment, the second ground pad 432 may be in contact with the inner surface 200a of the housing 200 facing the another surface 402 of the printed circuit board 400. For example, the second ground pad 432 may be electrically connected to the housing 200 including a conductive material by being in contact with the inner surface 200a of the housing 200. According to an embodiment, the at least one ground pad 430 may be connected to the first conductive via 411 disposed within the insertion hole 410. For example, the first ground pad 431 may be connected to the first conductive via 411. For example, the second ground pad 432 may be connected to the first conductive via 411. As the at least one ground pad 430 is connected to the first conductive via 411, the first conductive via 411 may be electrically connected to the at least one ground layer 420.

According to an embodiment, the at least one ground pad 430 may be electrically connected to the at least one ground layer 420 by at least one second conductive via 421. The at least one second conductive via 421 may connect the at least one ground layer 420 and the at least one ground pad 430 by extending through the at least one ground layer 420. In case that the at least one ground layer 420 includes a plurality of ground layers, the at least one second conductive via 421 may extend through the plurality of ground layers. According to an embodiment, the at least one second conductive via 421 may electrically connect the first ground pad 431 and the second ground pad 432. For example, the at least one second conductive via 421 may extend from the first ground pad 431 to the second ground pad 432 within the printed circuit board 400. According to an embodiment, the at least one second conductive via 421 may include a plurality of second conductive vias spaced apart from each other.

According to an embodiment, within a state in which the fastening member 500 is inserted into the insertion hole 410, the fastening member 500 may be in contact with the at least one ground pad 430. For example, the portion 500a of the fastening member 500 may be in contact with the first ground pad 431 disposed on the surface 401 of the printed circuit board 400. For example, the fastening member 500 may be in contact with the first conductive via 411 within the insertion hole 410. The fastening member 500 may be electrically connected to the at least one ground layer 420 by the fastening member 500 being in contact with the first ground pad 431. Since the fastening member 500 includes the conductive material, as the fastening member 500 is connected to the ground layer 420, an area of an electrical ground of the printed circuit board 400 may be expanded. As the ground of the printed circuit board 400 is expanded, the printed circuit board 400 may provide a structure in which an operation of the at least one electronic component 300 disposed on the printed circuit board 400 may be stabilized.

According to an embodiment, the printed circuit board 400 may include at least one test pad 440, a set of first conductive pads 450, a set of second conductive pads 460, a plurality of first conductive lines 470, and/or a plurality of second conductive lines 480.

According to an embodiment, the at least one test pad 440 may be utilized to identify whether the printed circuit board 400 operates normally within a process in which the printed circuit board 400 is manufactured. For example, the at least one test pad 440 may be utilized to identify whether the at least one electronic component 300 disposed on the printed circuit board 400 operates normally within the process in which the printed circuit board 400 is manufactured. For example, the at least one test pad 440 may be utilized to identify whether transmission of a signal to the at least one electronic component 300 through the printed circuit board 400 or transmission of a signal from the at least one electronic component 300 is performed normally within the process in which the printed circuit board 400 is manufactured. For example, the at least one test pad 440 may be utilized for tuning a signal of the at least one electronic component 300 within the process in which the printed circuit board 400 is manufactured. For example, the at least one test pad 440 may be referred to as a test point (TP), but is not limited thereto. According to an embodiment, the at least one test pad 440 may be exposed to the outside of the printed circuit board 400. For example, the at least one test pad 440 may include a plurality of first test pads 441 and a plurality of second test pads 442.

According to an embodiment, the plurality of first test pads 441 may be disposed on the surface 401 of the printed circuit board 400. For example, the plurality of first test pads 441 may be exposed on the surface 401 of the printed circuit board 400. According to an embodiment, the plurality of first test pads 441 may be spaced apart from each other. For example, the plurality of first test pads 441 may be spaced apart from each other in a circumferential direction of the insertion hole 410. The plurality of first test pads 441 may be electrically disconnected from each other. Since each of the plurality of first test pads 441 is electrically disconnected from each other, different signals may be transmitted or received. According to an embodiment, the plurality of first test pads 441 may be disposed along the insertion hole 410. For example, the plurality of first test pads 441 may cover the insertion hole 410. For example, the plurality of first test pads 441 may surround the insertion hole 410. According to an embodiment, the plurality of first test pads 441 may be spaced apart from the at least one ground pad 430. For example, the plurality of first test pads 441 may be spaced apart from the first ground pad 431 along a radial direction of the insertion hole 410. According to an embodiment, the plurality of first test pads 441 may be disposed along the first ground pad 431. For example, the plurality of first test pads 441 may cover the first ground pad 431. The plurality of first test pads 441 may surround the first ground pad 431. However, it is not limited thereto, and the plurality of first test pads 441 may be surrounded by the first ground pad 431.

The plurality of second test pads 442 may be disposed on the another surface 402 of the printed circuit board 400 opposite to the surface 401 of the printed circuit board 400. For example, the plurality of second test pads 442 may be exposed on the another surface 402 of the printed circuit board 400. The plurality of second test pads 442 may be spaced apart from each other. The plurality of second test pads 442 may be electrically disconnected from each other. Each of the plurality of second test pads 442 may transmit or receive different signals by being electrically disconnected from each other. According to an embodiment, the plurality of second test pads 442 may be disposed along the insertion hole 410. The plurality of second test pads 442 may be spaced apart from the second ground pad 432. For example, the plurality of second test pads 442 may be spaced apart from the second ground pad 432 along a radial direction of the insertion hole 410. According to an embodiment, the plurality of second test pads 442 may be disposed along the second ground pad 432. For example, the plurality of second test pads 442 may cover the second ground pad 432. For example, the plurality of second test pads 442 may surround the second ground pad 432. However, it is not limited thereto, and the plurality of second test pads 442 may be surrounded by the second ground pad 432. According to an embodiment, the plurality of second test pads 442 may be electrically disconnected from the plurality of first test pads 441. In FIG. 3B, it is illustrated that the printed circuit board 400 includes all of the plurality of first test pads 441 and the plurality of second test pads 442, but is not limited thereto. For example, the printed circuit board 400 may include only one of the plurality of first test pads 441 and the plurality of second test pads 442.

According to an embodiment, the set of first conductive pads 450 may be electrically connected to the at least one test pad 440. According to an embodiment, the set of first conductive pads 450 may be disposed on an electrical path between the at least one test pad 440 and the at least one electronic component 300. For example, the set of first conductive pads 450 may be disposed on an electrical path between the plurality of first test pads 441 and the at least one electronic component 300. For example, the set of first conductive pads 450 may be spaced apart from the insertion hole 410 along a first direction (e.g., a +x direction), which is a direction in which the at least one electronic component 300 is disposed in the insertion hole 410. According to an embodiment, the set of first conductive pads 450 may be spaced apart from each other. For example, the set of first conductive pads 450 may be spaced apart from each other along a second direction (e.g., a +y direction), perpendicular to the first direction (e.g., the +x direction), which is the direction toward the at least one electronic component 300 in the insertion hole 410. According to an embodiment, the set of first conductive pads 450 may be disposed on the surface 401 of the printed circuit board 400. For example, the set of first conductive pads 450 may be exposed on the surface 401 of the printed circuit board 400. According to an embodiment, the number of the set of first conductive pads 450 may correspond to the number of the at least one test pad 440. For example, the number of the set of first conductive pads 450 may correspond to a sum of the number of the plurality of first test pads 441 and the number of the plurality of second test pads 442.

According to an embodiment, the set of second conductive pads 460 may be electrically connected to the at least one electronic component 300. According to an embodiment, the set of second conductive pads 460 may be disposed between the set of first conductive pads 450 and the at least one electronic component 300. According to an embodiment, the set of second conductive pads 460 may be spaced apart from each other. For example, the set of second conductive pads 460 may be spaced apart from each other along a second direction (e.g., a +y direction). According to an embodiment, the set of second conductive pads 460 may be disposed on the surface 401 of the printed circuit board 400. For example, the set of second conductive pads 460 may be exposed on the surface 401 of the printed circuit board 400. According to an embodiment, the number of the set of second conductive pads 460 may correspond to the number of the set of first conductive pads 450. According to an embodiment, the set of second conductive pads 460 may be spaced apart from the set of first conductive pads 450 to be electrically disconnected. For example, the set of second conductive pads 460 may be spaced apart from the set of first conductive pads 450 along the first direction (e.g., the +x direction), which is the direction toward the at least one electronic component 300 in the insertion hole 410.

According to an embodiment, the plurality of first conductive lines 470 may connect the at least one test pad 440 and the set of first conductive pads 450. For example, the plurality of first conductive lines 470 may electrically connect the at least one test pad 440 and the set of first conductive pads 450. According to an embodiment, the plurality of first conductive lines 470 may be disposed within the printed circuit board 400. The plurality of first conductive lines 470 may extend from the at least one test pad 440 to the set of first conductive pads 450. For example, a first conductive line 471 of the plurality of first conductive lines 470 may extend from a first test pad 441a of the plurality of first test pads 441. The first conductive line 471 may extend from the first test pad 441a to a first conductive pad 451 of the set of first conductive pads 450. The first conductive line 471 may electrically connect the first test pad 441a and the first conductive pad 451. According to an embodiment, the number of the plurality of first conductive lines 470 may correspond to the number of the at least one test pad 440. For example, the number of the plurality of first conductive lines 470 may correspond to the number of the plurality of first test pads 441. For example, the number of the plurality of first conductive lines 470 may correspond to a sum of the number of the plurality of first test pads 441 and the number of the plurality of second test pads 442. According to an embodiment, the number of the plurality of first conductive lines 470 may correspond to the number of the set of first conductive pads 450.

According to an embodiment, the plurality of second conductive lines 480 may connect the set of second conductive pads 460 and the at least one electronic component 300. For example, the plurality of second conductive lines 480 may electrically connect the set of second conductive pads 460 and the at least one electronic component 300. According to an embodiment, the plurality of second conductive lines 480 may extend from the set of second conductive pads 460 to the at least one electronic component 300. For example, a second conductive line 481 of the plurality of second conductive lines 480 may extend from a second conductive pad 461 of the set of second conductive pads 460. The second conductive line 481 may extend from the second conductive pad 461 to the at least one electronic component 300. The second conductive line 481 may electrically connect the second conductive pad 461 to the at least one electronic component 300. According to an embodiment, the number of the plurality of second conductive lines 480 may correspond to the number of the set of first conductive pads 450. According to an embodiment, the plurality of second conductive lines 480 may be electrically disconnected from the at least one ground layer 420.

According to an embodiment, within the process in which the printed circuit board 400 is manufactured, the set of first conductive pads 450 and the set of second conductive pads 460 may be electrically connected. For example, the set of first conductive pads 450 and the set of second conductive pads 460 may be electrically connected through the solder attached on the surface 401 of the printed circuit board 400. For example, the first conductive pad 451 may be electrically connected to the second conductive pad 461 through the solder. Within a state in which the set of first conductive pads 450 and the set of second conductive pads 460 are electrically connected, at least one test probe for identifying whether the printed circuit board 400 operates normally may be in contact with the at least one test pad 440. A manufacturer of the printed circuit board 400 may identify whether the at least one electronic component 300 and the printed circuit board 400 operate normally based on transmitting a measurement signal to the at least one test pad 440 through at least one probe. After manufacture of the printed circuit board 400 is completed, the set of first conductive pads 450 and the set of second conductive pads 460 may be electrically disconnected. For example, the solder disposed between the set of first conductive pads 450 and the set of second conductive pads 460 may be removed after the manufacture of the printed circuit board 400 is completed. For example, a state in which the manufacture of the printed circuit board 400 is completed may mean a state in which the printed circuit board 400 is disposed within the housing 200.

According to an embodiment, the fastening member 500 may be in contact with the at least one test pad 440 within a state of being inserted into the insertion hole 410. For example, the portion 500a of the fastening member 500 may be in contact with the at least one test pad 440. For example, when the printed circuit board 400 is viewed from above (e.g., the +z direction), the fastening member 500 may overlap the at least one test pad 440 and the at least one ground pad 430. For example, when the printed circuit board 400 is viewed in the direction (e.g., the −z direction) in which the another surface 402 of the printed circuit board 400 faces, the fastening member 500 may overlap the at least one test pad 440 and the at least one ground pad 430. For example, the fastening member 500 may be in contact with the plurality of first test pads 441. As the fastening member 500 is in contact with the plurality of first test pads 441, the plurality of first test pads 441 may be electrically connected to the at least one ground layer 420 through the fastening member 500. As the plurality of first test pads 441 are electrically connected to the at least one ground layer 420, the plurality of first conductive lines 470 and the set of first conductive pads 450 may be electrically connected to the at least one ground layer 420. As the plurality of first test pads 441, the plurality of first conductive lines 470, and the set of first conductive pads 450 are electrically connected to the at least one ground layer 420, an area of the ground of the printed circuit board 400 may be expanded. For example, in case that the at least one test pad 440 is omitted within the state in which the manufacture of the printed circuit board 400 is completed, a specification of the printed circuit board 400 considered in the manufacturing process may be changed. In case that the specification of the printed circuit board 400 considered in the manufacturing process is changed, the printed circuit board 400 whose manufacture is completed have deteriorated performance. For example, in case that the at least one test pad 440 may not be utilized as a ground, a space on the printed circuit board 400 may be wasted by the at least one test pad 440. Since the at least one test pad 440 is electrically connected to the at least one ground layer 420 through the fastening member 500, the electronic device 101 according to an embodiment may provide a structure capable of utilizing the at least one test pad 440 as the ground within the state in which the manufacture of the printed circuit board 400 is completed.

According to an embodiment, within the state in which the manufacture of the printed circuit board 400 is completed, the set of second conductive pads 460 may be electrically disconnected from the at least one ground layer 420 by being electrically disconnected from the set of first conductive pads 450. For example, in case that the set of second conductive pads 460 and the set of first conductive pads 450 are electrically connected to each other, the set of second conductive pads 460 and the at least one ground layer 420 may be electrically connected, as the fastening member 500 is inserted into the insertion hole 410. In case that the set of second conductive pads 460 and the at least one ground layer 420 are electrically connected to each other, the at least one ground layer 420 and at least one electronic component 300 may be electrically connected to each other through the plurality of second conductive lines 480. In case that the at least one ground layer 420 and the at least one electronic component 300 are electrically connected to each other, a short circuit may occur. According to an embodiment, the electronic device 101 may provide a structure having an extended ground while the at least one electronic component 300 operates normally since the set of first conductive pads 450 is electrically disconnected from the set of second conductive pads 460 within the state in which the manufacture of the printed circuit board 400 is completed.

According to an embodiment, the set of second conductive pads 460 may be disposed adjacent to the at least one electronic component 300. A distance between the at least one electronic component 300 and the set of second conductive pads 460 may be shorter than a distance between the set of first conductive pads 450 and the at least one test pad 440. For example, a distance between the at least one electronic component 300 and the second conductive pad 461 of the set of second conductive pads 460 may be shorter than a distance between the first conductive pad 451 of the set of first conductive pads 450 and the first test pad 441a. According to an embodiment, a length of the plurality of second conductive lines 480 may be shorter than a length of the plurality of first conductive lines 470. For example, a length of the second conductive line 481 of the plurality of second conductive lines 480 may be shorter than a length of the first conductive line 471 of the plurality of first conductive lines 470. As the set of first conductive pads 450 and the set of second conductive pads 460 are electrically disconnected from each other, the set of second conductive pads 460 and the plurality of second conductive lines 480 may operate as a stub generating noise within the printed circuit board 400. A distance between the set of second conductive pads 460 and the at least one electronic component 300 may form a stub length. As the stub length is longer, generation of the noise within the printed circuit board 400 may be increased. According to an embodiment, the electronic device 101 may provide a structure capable of reducing the generation of the noise since the set of second conductive pads 460 is disposed adjacent to at least one electronic component 300.

As described above, according to an embodiment, the electronic device 101 may provide a structure capable of expanding the ground of the printed circuit board 400 since the at least one test pad 440 is electrically connected to the at least one ground layer 420 through the fastening member 500.

Meanwhile, in FIG. 3A, the number of the at least one electronic component 300 is illustrated as one, but is not limited thereto. For example, the number of the at least one electronic component 300 may be two or more.

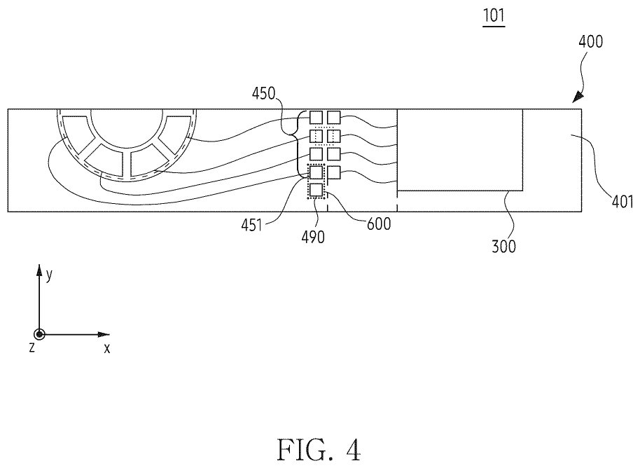

FIG. 4 is a top plan view of a printed circuit board according to an embodiment of the disclosure.

Referring to FIG. 4, according to an embodiment, a printed circuit board 400 may include an exposed pad 490. The exposed pad 490 may be disposed on a surface 401 of the printed circuit board 400. The exposed pad 490 may be exposed on the surface 401 of the printed circuit board 400. According to an embodiment, the exposed pad 490 may be spaced apart from a first conductive pad 451. For example, the exposed pad 490 may be spaced apart from the first conductive pad 451 in a third direction (e.g., a −y direction) opposite to a second direction (e.g., a +y direction). According to an embodiment, the exposed pad 490 may be electrically connected to at least one ground layer (e.g., the at least one ground layer 420 of FIG. 3B) within the printed circuit board 400.

According to an embodiment, the electronic device 101 may include another electronic component 600. The another electronic component 600 may be disposed on the surface 401 of the printed circuit board 400. For example, the another electronic component 600 may be disposed on the exposed pad 490 and the first conductive pad 451. However, it is not limited thereto, and the another electronic component 600 may be disposed on a portion of a set of first conductive pads 450. According to an embodiment, the another electronic component 600 may be electrically connected to the at least one ground layer 420 within the printed circuit board 400. The another electronic component 600 may include a passive element. The passive element (e.g., a resistor, an inductor, or a capacitor) may be configured not to deform a received electrical signal. For example, the another electronic component 600 may include a varistor for reducing damage to the printed circuit board 400 due to a voltage above a rated voltage. The varistor may have a relatively high resistance value in case that a voltage within a specified voltage is applied, and may have a relatively low resistance value in case that a voltage exceeding a specified voltage is applied. As the varistor has the relatively low resistance value when the voltage exceeding the specified voltage is applied, it may bypass a current exceeding the rated voltage introduced into the printed circuit board 400 to the ground.

As described above, according to an embodiment, the electronic device 101 may provide a structure capable of reducing damage to the printed circuit board 400 due to an overcurrent, by the another electronic component 600 that bypasses the overcurrent introduced into the printed circuit board 400.

The printed circuit board of the electronic device may include a structure capable of performing various functions in addition to a conductive layer for transmitting data between electronic components. For example, the printed circuit board may include at least one pad that may be electrically connected to the electronic components on the printed circuit board, and a hole that may accommodate the fastening member for fastening the printed circuit board. As the at least one pad and the hole are disposed, a space in which the electronic components may be disposed on the printed circuit board may be decreased. The printed circuit board may need a structure capable of utilizing the hole accommodating the fastening member within the miniaturized electronic device.

According to an embodiment, an electronic device (e.g., the electronic device 101 of FIGS. 3A and 3B) may comprise a housing (e.g., the housing 200 of FIGS. 3A and 3B). According to an embodiment, the electronic device may comprise a printed circuit board (e.g., the printed circuit board 400 of FIGS. 3A and 3B) including an insertion hole (e.g., the insertion hole 410 of FIGS. 3A and 3B), disposed within the housing. According to an embodiment, the electronic device may comprise at least one electronic component (e.g., the electronic component 300 of FIG. 3A) disposed on a surface (e.g., the surface 401 of FIGS. 3A and 3B) of the printed circuit board. According to an embodiment, the electronic device may comprise a fastening member (e.g., the fastening member 500 of FIGS. 3A and 3B) inserted into the insertion hole to fasten the printed circuit board to the housing. According to an embodiment, the printed circuit board may include a ground pad (e.g., the ground pad 430 of FIGS. 3A and 3B) disposed on the surface of the printed circuit board along the insertion hole. According to an embodiment, the printed circuit board may include a test pad (e.g., the test pad 440 of FIGS. 3A and 3B) disposed on the surface of the printed circuit board along the ground pad. According to an embodiment, the printed circuit board may include a first conductive pad (e.g., the first conductive pad 451 of FIG. 3A), disposed between the test pad and the electronic component, electrically connected to the test pad. According to an embodiment, the printed circuit board may include a second conductive pad (e.g., the second conductive pad 461 of FIG. 3A), disposed between the first conductive pad and the electronic component, spaced apart from the first conductive pad to be electrically disconnected from the first conductive pad, and electrically connected to the electronic component. According to an embodiment, the fastening member may be electrically connected to the ground pad and the test pad by a portion (e.g., the portion 500a of FIGS. 3A and 3B) of the fastening member being in contact with the ground pad and the test pad.

According to an embodiment, the fastening member may be electrically connected to the housing by another portion (e.g., the another portion 500b of FIG. 3B) of the fastening member being in contact with the housing.

According to an embodiment, the printed circuit board may include a first conductive line (e.g., the first conductive line 471 of FIG. 3A) extending from the first conductive pad to the test pad. According to an embodiment, the printed circuit board may include a second conductive line (e.g., the second conductive line 481 of FIG. 3A), electrically disconnected from the first conductive line, extending from the second conductive pad to the electronic component in the printed circuit board.

According to an embodiment, a distance between the electronic component and the second conductive pad may be shorter than a distance between the first conductive pad and the test pad.

According to an embodiment, the printed circuit board may include a ground layer (e.g., the ground layer 420 of FIG. 3B) disposed within the printed circuit board. According to an embodiment, the printed circuit board may include a conductive via (e.g., the second conductive via 421 of FIG. 3B) electrically connecting the ground layer and the ground pad by extending through the ground layer.

According to an embodiment, the ground layer may include a plurality of ground layers stacked on each other within the printed circuit board. According to an embodiment, the conductive via may extend through the plurality of ground layers.

According to an embodiment, the printed circuit board may include another ground pad (e.g., the second ground pad 432 of FIG. 3B) disposed on another surface (e.g., the another surface 402 of FIG. 3B) of the printed circuit board opposite to the surface of the printed circuit board. According to an embodiment, the printed circuit board may include a conductive via (e.g., the second conductive via 421 of FIG. 3B) electrically connecting the ground pad and the another ground pad by extending from the ground pad to the another ground pad within the printed circuit board.

According to an embodiment, the housing may include an inner surface (e.g., the inner surface 200a of FIG. 3B) facing the another surface of the printed circuit board. According to an embodiment, the another ground pad may be electrically connected to the housing by being in contact with the inner surface.

According to an embodiment, the test pad may include a plurality of test pads (e.g., the plurality of first test pads 441 of FIGS. 3A and 3B) spaced apart from each other.

According to an embodiment, the first conductive pad may include a set of first conductive pads (e.g., the set of first conductive pads 450 of FIG. 3A), spaced apart from the second conductive pad in a first direction, electrically connected to the test pad spaced apart from each other in a second direction perpendicular to the first direction. According to an embodiment, the second conductive pad may include a set of second conductive pads (e.g., the set of second conductive pads 460 of FIG. 3A), electrically disconnected from each of the set of first conductive pads, electrically connected to the electronic component spaced apart from each other in the second direction. According to an embodiment, a number of the plurality of test pads may correspond to a number of the set of the first conductive pads.

According to an embodiment, the test pad may be spaced apart from the ground pad along a radial direction of the insertion hole.

According to an embodiment, the printed circuit board may include another test pad (e.g., the plurality of second test pads 442 of FIG. 3B), disposed on another surface of the printed circuit board opposite to the surface of the printed circuit board along the insertion hole.

According to an embodiment, the first conductive pad may be electrically connected to the ground pad by the portion of the fastening member being in contact with the test pad.

According to an embodiment, the fastening member may cover the test pad and the ground pad when the printed circuit board is viewed from above.

According to an embodiment, the first conductive pad may be spaced apart from the second conductive pad in a first direction. The printed circuit board may include an exposed pad (e.g., the exposed pad 490 of FIG. 4) spaced apart from the first conductive pad in a second direction perpendicular to the first direction. According to an embodiment, the printed circuit board may include another electronic component (e.g., the another electronic component 600 of FIG. 4) electrically connected to the ground pad by being disposed on the exposed pad and the first conductive pad.

According to an embodiment, an electronic device (e.g., the electronic device 101 of FIGS. 3A and 3B) may comprise a housing (e.g., the housing 200 of FIGS. 3A and 3B). According to an embodiment, the electronic device may comprise a printed circuit board (e.g., the printed circuit board 400 of FIGS. 3A and 3B), including an insertion hole (e.g., the insertion hole 410 of FIGS. 3A and 3B), disposed within the housing. According to an embodiment, the electronic device may comprise at least one electronic component (e.g., the electronic component 300 of FIG. 3A) disposed on a surface (e.g., the surface 401 of FIGS. 3A and 3B) of the printed circuit board. According to an embodiment, the electronic device may comprise a fastening member (e.g., the fastening member 500 of FIGS. 3A and 3B) fastening the printed circuit board into the housing by being inserted into the insertion hole. According to an embodiment, the printed circuit board may include a ground pad (e.g., the ground pad 430 of FIGS. 3A and 3B) disposed along the insertion hole. According to an embodiment, the printed circuit board may include a plurality of test pads, surrounding the ground pad, exposed on the surface of the printed circuit board, and spaced apart from each other. According to an embodiment, the printed circuit board may include sets of a plurality of conductive pads that include a first conductive pad (e.g., the first conductive pad 451 of FIG. 3A) and a second conductive pad (e.g., the second conductive pad 461 of FIG. 3A) spaced apart from the first conductive pad to be electrically disconnected from the first conductive pad and that are disposed between the insertion hole and the electronic component. According to an embodiment, the printed circuit board may include a first conductive line (e.g., the first conductive line 471 of FIG. 3A) connecting the first conductive pad and one (e.g., the first test pad 441a of FIG. 3A) of the plurality of test pads. According to an embodiment, the printed circuit board may include a second conductive line (e.g., the second conductive line 481 of FIG. 3A) connecting the second conductive pad and the electronic component. According to an embodiment, the printed circuit board may include a ground layer (e.g., the ground layer 420 of FIG. 3B), electrically disconnected from the second conductive line, electrically connected to the ground pad. According to an embodiment, the fastening member may be electrically connected to the ground layer by a portion (e.g., the portion 500a of FIGS. 3A and 3B) of the fastening member being in contact with at least some of the ground pad and the plurality of test pads.

According to an embodiment, the fastening member may be electrically connected to the housing by another portion of the fastening member being in contact with the housing.

According to an embodiment, a distance between the electronic component and the second conductive pad may be shorter than a distance between the first conductive pad and one of the plurality of test pads.

According to an embodiment, the printed circuit board may include another ground pad (e.g., the second ground pad 432 of FIG. 3B) disposed on another surface of the printed circuit board opposite to the surface of the printed circuit board. According to an embodiment, the printed circuit board may include a conductive via (e.g., the second conductive via 421 of FIG. 3B) electrically connecting the ground pad and the another ground pad by extending from the ground pad to the another ground pad within the printed circuit board.

According to an embodiment, the plurality of test pads may be spaced apart from the ground pad along a radial direction of the insertion hole.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1^{st}” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively,” as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry.” A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a housing;
a printed circuit board, including an insertion hole, disposed within the housing;
at least one electronic component disposed on a surface of the printed circuit board; and
a fastening member inserted into the insertion hole to fasten the printed circuit board to the housing,
wherein the printed circuit board further includes:
a ground pad disposed on the surface of the printed circuit board along the insertion hole,
a test pad disposed on the surface of the printed circuit board along the ground pad,
a first conductive pad, disposed between the test pad and the electronic component, electrically connected to the test pad, and
a second conductive pad, disposed between the first conductive pad and the electronic component, spaced apart from the first conductive pad to be electrically disconnected from the first conductive pad, and electrically connected to the electronic component, and
wherein the fastening member is electrically connected to the ground pad and the test pad by a portion of the fastening member being in contact with the ground pad and the test pad.

2. The electronic device of claim 1, wherein the fastening member is electrically connected to the housing by another portion of the fastening member being in contact with the housing.

3. The electronic device of claim 1, wherein the printed circuit board further includes:
a first conductive line extending from the first conductive pad to the test pad; and
a second conductive line, electrically disconnected from the first conductive line, extending from the second conductive pad to the electronic component in the printed circuit board.

4. The electronic device of claim 1, wherein a distance between the electronic component and the second conductive pad is shorter than a distance between the first conductive pad and the test pad.

5. The electronic device of claim 1, wherein the printed circuit board further includes:
a ground layer disposed within the printed circuit board; and
a conductive via electrically connecting the ground layer and the ground pad by extending through the ground layer.

6. The electronic device of claim 5,
wherein the ground layer includes a plurality of ground layers stacked on each other within the printed circuit board, and
wherein the conductive via extends through the plurality of ground layers.

7. The electronic device of claim 1, wherein the printed circuit board further includes:
another ground pad disposed on another surface of the printed circuit board opposite to the surface of the printed circuit board; and
a conductive via electrically connecting the ground pad and the another ground pad by extending from the ground pad to the another ground pad within the printed circuit board.

8. The electronic device of claim 7,
wherein the housing further includes an inner surface facing the another surface of the printed circuit board, and
wherein the another ground pad is electrically connected to the housing by being in contact with the inner surface.

9. The electronic device of claim 1, wherein the test pad includes a plurality of test pads spaced apart from each other.

10. The electronic device of claim 9, comprising:
a set of first conductive pads, including the first conductive pad, spaced apart from the second conductive pad in a first direction, and electrically connected to the plurality of test pads,
wherein conductive pads included in the set of first conductive pads are spaced apart from each other in a second direction perpendicular to the first direction; and
a set of second conductive pads, including the second conductive pad, electrically disconnected from the set of first conductive pads, and electrically connected to the electronic component,
wherein conductive pads included in the set of second conductive pads are spaced apart from each other in the second direction, and
wherein a number of the plurality of test pads corresponds to a number of the conductive pads included in the set of first conductive pads.

11. The electronic device of claim 1, wherein the test pad is spaced apart from the ground pad along a radial direction of the insertion hole.

12. The electronic device of claim 1, wherein the printed circuit board further includes another test pad, disposed on another surface of the printed circuit board opposite to the surface of the printed circuit board along the insertion hole.

13. The electronic device of claim 1, wherein the first conductive pad is electrically connected to the ground pad by the portion of the fastening member being in contact with the test pad.

14. The electronic device of claim 1, wherein the fastening member covers the test pad and the ground pad when the printed circuit board is viewed from above.

15. The electronic device of claim 1,
wherein the first conductive pad is spaced apart from the second conductive pad in a first direction, and
wherein the printed circuit board further includes:
an exposed pad spaced apart from the first conductive pad in a second direction perpendicular to the first direction, and
another electronic component electrically connected to the ground pad by being disposed on the exposed pad and the first conductive pad.

16. An electronic device comprising:
a housing;
a printed circuit board, including an insertion hole, disposed within the housing;
at least one electronic component disposed on a surface of the printed circuit board; and
a fastening member fastening the printed circuit board into the housing by being inserted into the insertion hole,
wherein the printed circuit board further includes:
a ground pad disposed along the insertion hole,
a plurality of test pads, surrounding the ground pad, exposed on the surface of the printed circuit board, and spaced apart from each other,
sets of a plurality of conductive pads that include a first conductive pad and a second conductive pad spaced apart from the first conductive pad to be electrically disconnected from the first conductive pad and that are disposed between the insertion hole and the electronic component,
a first conductive line connecting the first conductive pad and one of the plurality of test pads,
a second conductive line connecting the second conductive pad and the electronic component, and
a ground layer, electrically disconnected from the second conductive line, electrically connected to the ground pad, and
wherein the fastening member is electrically connected to the ground layer by a portion of the fastening member being in contact with at least some of the ground pad and the plurality of test pads.

17. The electronic device of claim 16, wherein a distance between the electronic component and the second conductive pad is shorter than a distance between the first conductive pad and the one of the plurality of test pads.

18. The electronic device of claim 16, wherein the printed circuit board further includes:
another ground pad disposed on another surface of the printed circuit board opposite to the surface of the printed circuit board; and
a conductive via electrically connecting the ground pad and the another ground pad by extending from the ground pad to the another ground pad within the printed circuit board.

19. The electronic device of claim 16, wherein the fastening member is electrically connected to the housing by another portion of the fastening member being in contact with the housing.

20. The electronic device of claim 16, wherein the plurality of test pads are spaced apart from the ground pad along a radial direction of the insertion hole.
